(19) United States
(12) Patent Application Publication
(10) Pub. No.: US 2013/0277787 A1
(43) Pub. Date: Oct. 24, 2013

(54) BACKSIDE ILLUMINATION CMOS IMAGE SENSOR AND METHOD FOR FABRICATING THE SAME

(71) Applicant: DONGBU HITEK CO., LTD., Seoul (KR)

(72) Inventor: Sunghyok KIM, Seoul (KR)

(73) Assignee: Dongbu HiTek Co., Ltd., Seoul (KR)

(21) Appl. No.: 13/734,181

(22) Filed: Jan. 4, 2013

(30) Foreign Application Priority Data
Apr. 23, 2012 (KR) 10-2012-0042158

(51) Int. Cl. H01L 31/0232; H01L 31/18

(52) U.S. Cl. CPC H01L 31/0232; H01L 31/18
USPC 257/432; 438/70

(57) ABSTRACT

A method of manufacturing a backside illumination CMOS image sensor includes bonding a first substrate and a second substrate, the first substrate including an epitaxial layer in which a photodiode region is defined. The method further includes removing the first substrate to expose the epitaxial layer, patterning the epitaxial layer to form a deep trench for separating pixels, forming a first passivation layer on/over the epitaxial layer with the deep trench formed therein, and sequentially forming a color filter and a lens on/over a top region of the first passivation layer corresponding to the epitaxial layer separated by the deep trench.

The present application claims priority under 35 U.S.C. 119 and 35 U.S.C. 365 to Korean Patent Application No. 10-2012-0042158 (filed on Apr. 23, 2012), which is hereby incorporated by reference in its entirety.

### BACKGROUND

Backside illumination image sensors are devices in which a microlens and photodiode of an image sensor are formed on a backside of a wafer, which may increase illumination efficiency. In related art frontside illumination image sensors, by increasing illumination efficiency, limitations in increasing resolution may be overcome and sensitivity degradation by a metal line may be avoided.

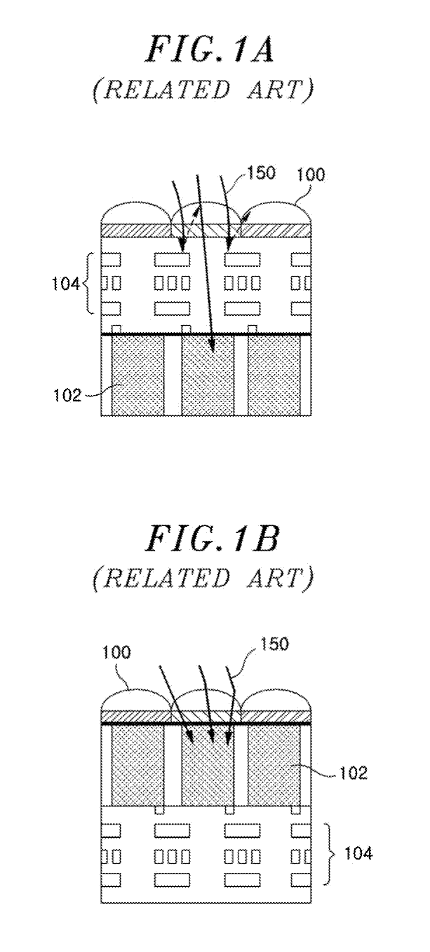

Related art FIGS. 1A and 1B illustrate sectional views of a frontside illumination image sensor and backside illumination image sensor respectively, in accordance with the related art. In the frontside illumination image sensor illustrated in FIG. 1A, a microlens 100 may be formed on a frontside of a wafer and light 150 that passes through the microlens 100 may be not efficiently transferred to a photodiode 102 due to interference from a metal line part 104 because the photodiode 102 may be disposed under the metal interconnection part 104.

In the backside illumination image sensor illustrated in FIG. 1B, a microlens 100 may be formed at a backside of a wafer and light 150 that passes through the microlens 100 may be directly received by a photodiode 102, which may enhance light illumination efficiency.

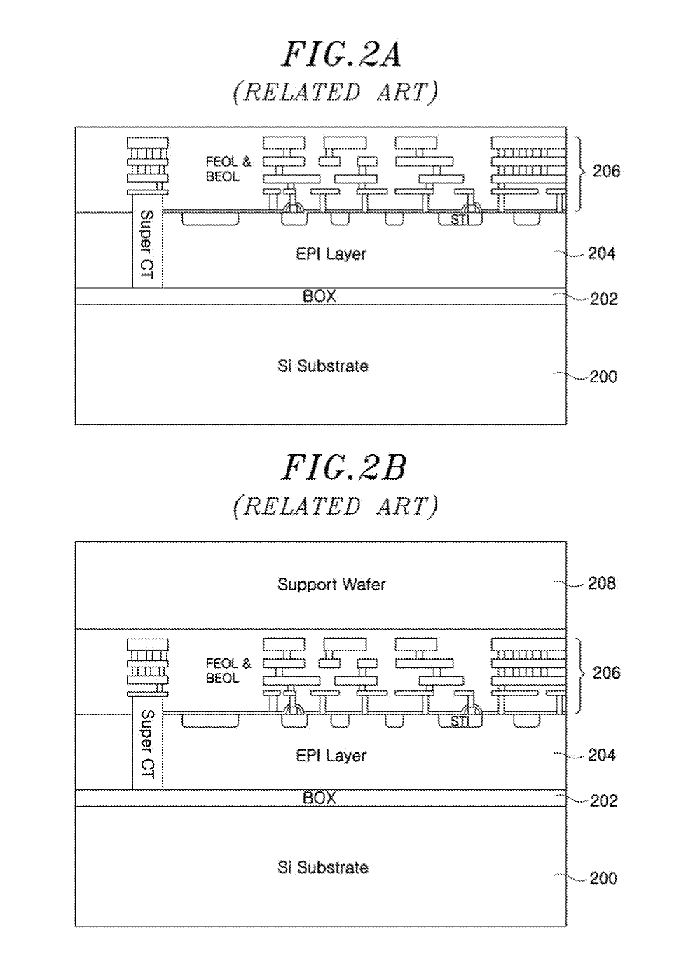

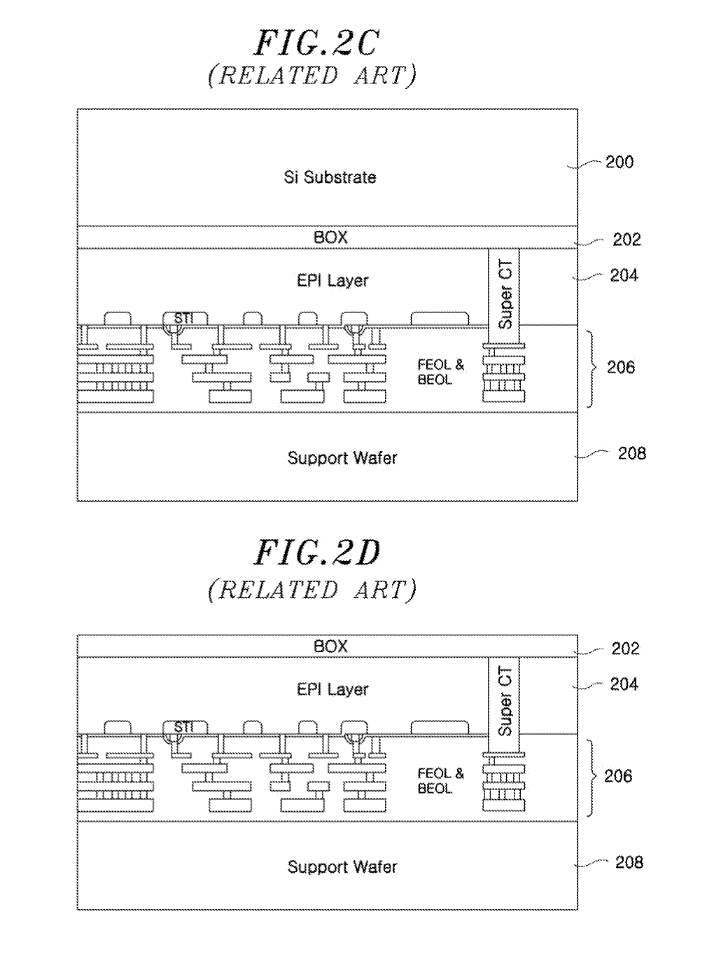

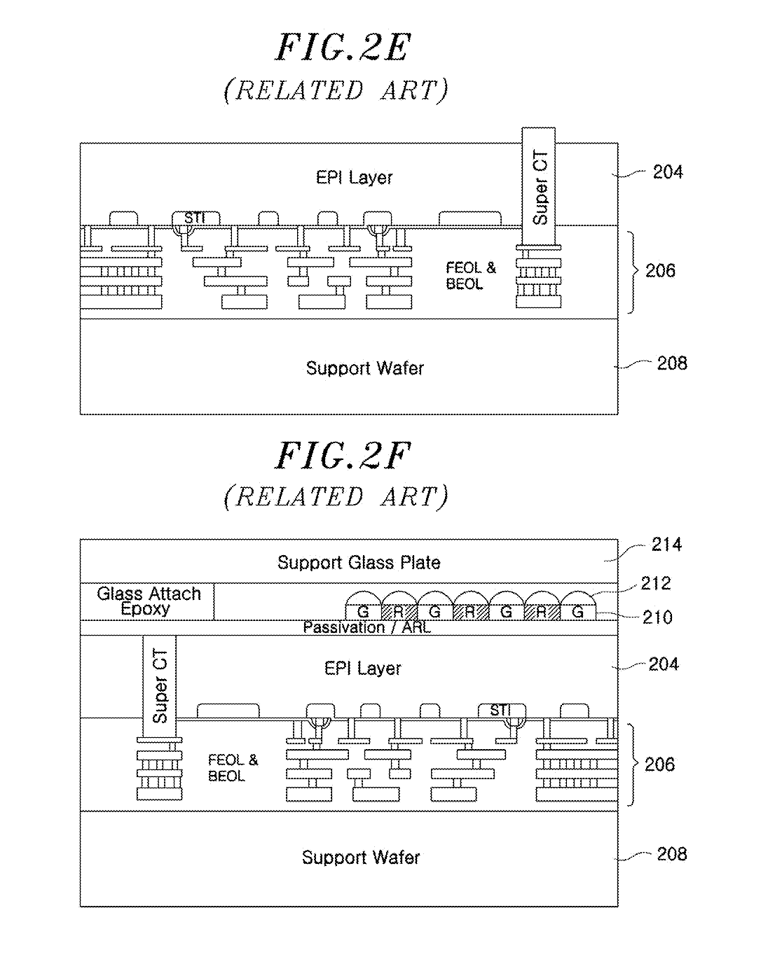

FIGS. 2A to 2F illustrate sectional views of a process of manufacturing a backside illumination image sensor using an SOI wafer, in accordance with the related art. As illustrated in FIG. 2A, a metal line 206 for an image sensor may be formed on an epitaxial layer 204 by performing a CIS process using an SOI wafer. As illustrated in FIG. 2B, a support wafer 208 may be bonded to an upper end of a wafer in which a CMOS process has been performed for thinning the wafer, through a wafer bonding process. As illustrated in FIG. 2C, the bonded support wafer 208 may be fixed. A grinding and chemical mechanical polishing (CMP) process may then be performed on a Si substrate 200 to remove the Si substrate 200, thereby exposing buried oxide (BOX) 202, as illustrated in FIG. 2D. As illustrated in FIG. 2E, the BOX 202 may be removed through wet etching and the epitaxial layer 204 in which a photodiode will be formed may remain. As illustrated in FIG. 2F, a color filter 210, a microlens 212, and a support glass plate 214 may be sequentially formed over the epitaxial layer 204, thereby finishing the backside illumination image sensor.

In the process of manufacturing a backside illumination image sensor, Si oxide may be required as the etch stop layer for performing a wafer thinning process (e.g. a process that leaves a portion of silicon equal to the thickness of a photodiode on a wafer and removes the other portion of silicon). In this case, oxide may be required to be disposed under silicon, and thus, an SOI (silicon on insulator) wafer in which a buried oxide may be disposed between Si layers may be used as a substrate.

By increasing a fill factor that may be an area actually receiving light, the backside illumination image sensor having the above-described structure may generate better images than the frontside illumination image sensor.

However, the backside illumination image and the frontside illumination image sensor suffer from deterioration and distortion in image characteristic due to interference between adjacent pixels. Particularly, as a pixel size decreases, the interference may increase.

### SUMMARY

Embodiments relate to a complementary metal-oxide semiconductor (CMOS) image sensor (CIS). Particular embodiments relate to a backside illumination CMOS image sensor and a method of manufacturing the same that minimizes an interference effect between adjacent pixels. The object of embodiments may not be limited to the aforesaid, but other objectives not described herein may be clearly understood by those skilled in the art from descriptions below.

Embodiments relate to a method of manufacturing a backside illumination CMOS image sensor, which includes at least one of: (1) bonding a first substrate and a second substrate, the first substrate including an epitaxial layer in which a photodiode region is defined; (2) removing the first substrate to expose the epitaxial layer; (3) patterning the epitaxial layer to form a deep trench for separating pixels; (4) forming a first passivation layer on the epitaxial layer with the deep trench formed therein; and (5) sequentially forming a color filter and a lens on a top region of the first passivation layer corresponding to the epitaxial layer separated by the deep trench.

In embodiments, the forming the deep trench includes patterning the epitaxial layer to pass through a partial region of the epitaxial layer to form the deep trench. In embodiments, the forming the deep trench comprises patterning the epitaxial layer to form the deep trench, the deep trench almost passing through a partial region of the epitaxial layer during patterning. In embodiments, the method further includes forming a light shielding layer on a region of the first passivation layer corresponding to the deep trench. In embodiments, the method further includes forming a second passivation layer on the first passivation layer in which the light shielding layer has been formed. In embodiments, the sequentially forming the color filter and the lens includes sequentially forming the color filter and the lens on the second passivation layer.

In embodiments, the forming the deep trench includes at least one of: (1) forming a photoresist pattern on the epitaxial layer, a region of the photoresist pattern corresponding to the deep trench being opened; and (2) opening a partial region of the epitaxial layer to form the deep trench, through an etching process, wherein the photoresist pattern is used as an etch mask during the etching process.

In embodiments, the deep trench is gap-filled with material which is deposited in forming the first passivation layer. In embodiments, a backside illumination CMOS image sensor is formed by bonding first and second substrates including the epitaxial layer in which a photodiode region is defined and then removing the first substrate, includes at least one of: (1) a deep trench formed for separating pixels by patterning the epitaxial layer; (2) a first passivation layer formed on the epitaxial layer with the deep trench formed therein; and (3) a color filter and a lens sequentially formed on a top region of the first passivation layer corresponding to the epitaxial layer region separated by the deep trench.

In embodiments, the deep trench is formed to slightly pass through a partial region of the epitaxial layer. In embodiments, the deep trench is formed to deeply pass through a partial region of the epitaxial layer. In embodiments, the backside illumination image sensor includes at least one of: (1) a light shielding layer formed on a region of the first passivation layer corresponding to the deep trench; and (2) a second passivation layer formed on the first passivation layer in which the light shielding layer has been formed. In embodiments, the deep trench is gap-filled by the first passivation layer.

### DRAWINGS

The above and other objects and features of embodiments will become apparent from the following description of embodiments, given in conjunction with the accompanying drawings, in which:

Example FIG. 1A is a sectional view of a frontside illumination image sensor, in accordance with the related art.

Example FIG. 1B is a sectional view of a backside illumination image sensor, in accordance with the related art.

Example FIGS. 2A to 2F are sectional views of a process of manufacturing a backside illumination image sensor, in accordance with the related art.

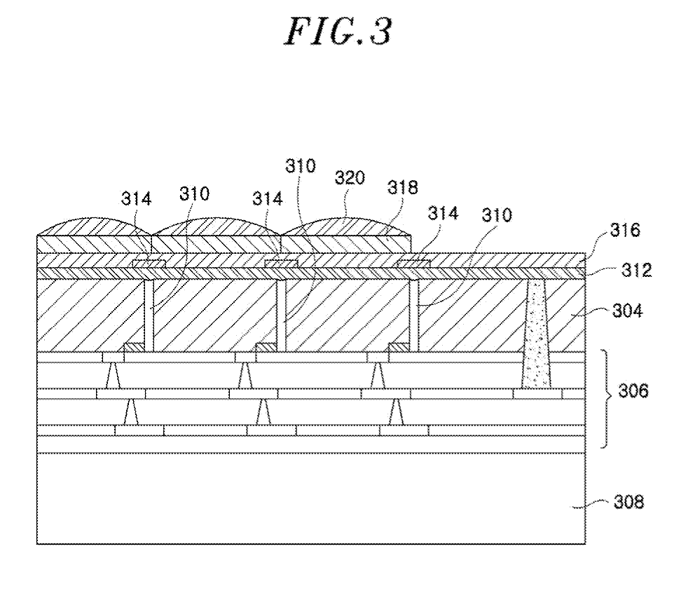

Example FIG. 3 is a sectional view of describing a structure of a backside illumination image sensor, in accordance with embodiments.

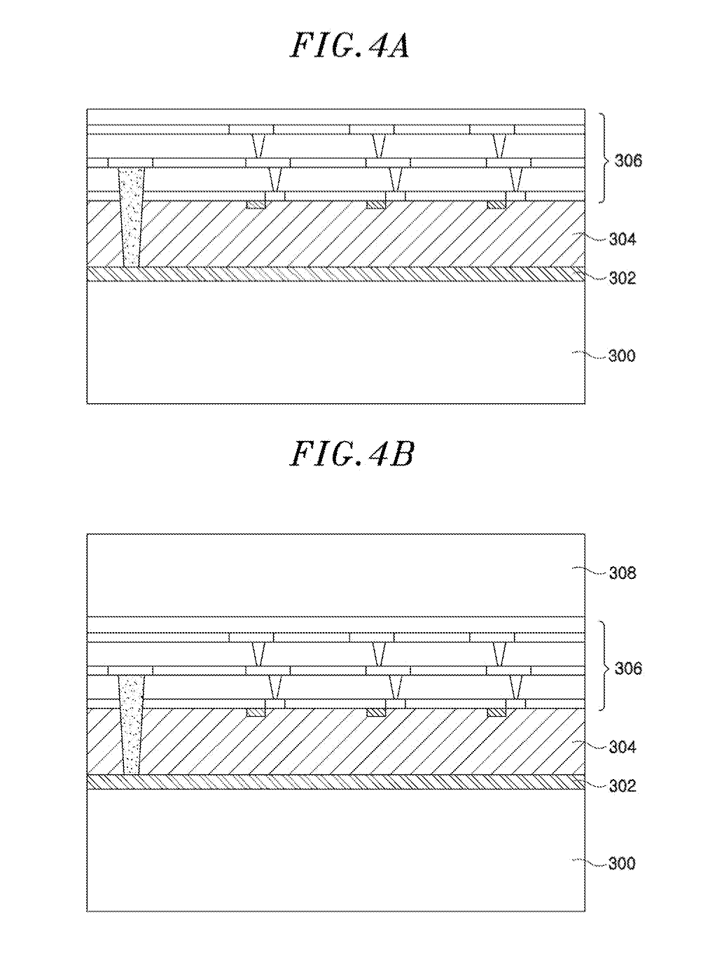

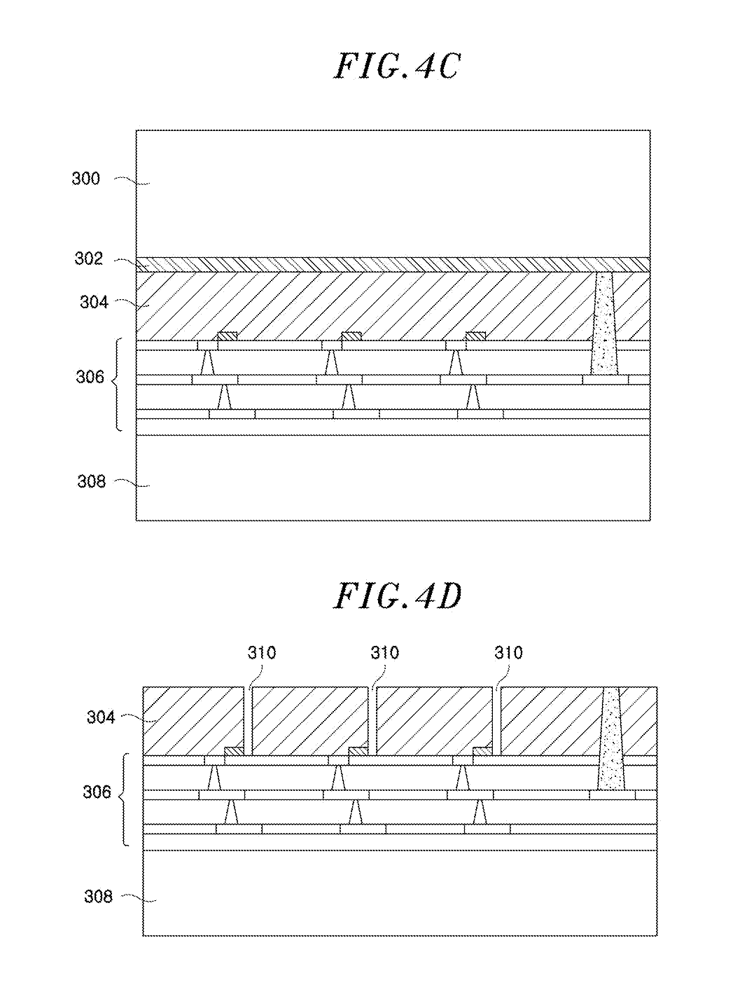

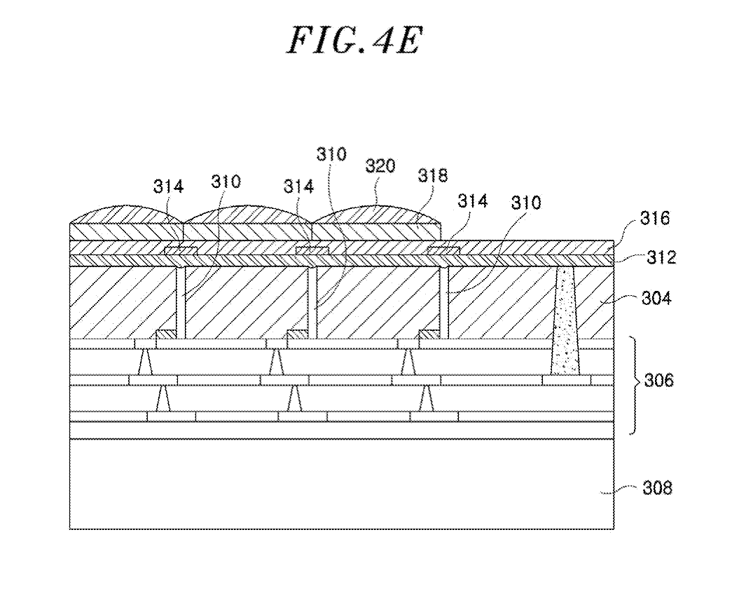

Example FIGS. 4A to 4E are sectional views illustrating a process of manufacturing the backside illumination image sensor, in accordance with embodiments.

### DESCRIPTION

The advantages and features of embodiments and methods of accomplishing these will be clearly understood from the following description taken in conjunction with the accompanying drawings. However, embodiments are not limited to those embodiments described, as embodiments may be implemented in various forms. It should be noted that the present embodiments are provided to make a full disclosure and also to allow those skilled in the art to know the full range of the embodiments. Therefore, the embodiments are to be defined only by the scope of the appended claims.

Embodiments relate to a backside illumination CMOS image sensor and a method of manufacturing the same, which may minimize interference between adjacent pixels, which is described in detail with reference to the accompanying drawings.

Example FIG. 3 is a sectional view illustrating a structure of a backside illumination CMOS image sensor, in accordance with embodiments. A carrier Si substrate 308 may be bonded to a Si substrate 300 including an epitaxial layer 304 in which a photodiode region may be defined. Then the Si substrate 300 may be removed, thereby forming the backside illumination image sensor, in accordance with embodiments. The backside illumination image sensor may include at least one of: (1) a deep trench 310 that may be formed for separating pixels by patterning the epitaxial layer 304; and (2) a first passivation layer 312, light shielding layers 314, and a second passivation layer 316 that are sequentially formed on the epitaxial layer 304 with the deep trench 310 formed therein. In embodiments, the light shielding layers 314 may be formed in partial regions of a top of the passivation layer 312.

In embodiments, the backside illumination image sensor may include color filters 318 and microlens 320 that may be formed on the second passivation layer 316 (e.g. on a top region of the second passivation layer 316 corresponding to the respective epitaxial layer 304 regions that may be separated by the deep trench 310). The width of the deep trench 310 may be narrow to have about 0.001 μm to 5 μm. The narrow width of the deep trench 310 may enable the deep trench 310 to maintain a void space or a passivation state in forming the first passivation layer 312.

In embodiments, although it has been described above as an example that the deep trench 310 maintains the void space, the deep trench 310 may be gap-filled with materials that may be deposited in forming the first passivation layer 312.

A process of manufacturing the backside illumination image sensor having the above-described structure will now be described in detail with reference to FIGS. 4A to 4E. in accordance with embodiments. Example FIGS. 4A to 4E are sectional views illustrating a process of manufacturing the backside illumination image sensor, in accordance with embodiments.

As illustrated in FIG. 4A, the epitaxial layer 304 may be formed using the Si substrate 300. A metal line 306 for an image sensor may then be formed by performing a CIS process on the epitaxial layer 304. In embodiments, the Si substrate 300 may be an SOI (silicon on insulator) wafer, in which case a BOX (buried oxide) 302 may be formed between the Si substrate 300 and the epitaxial layer 304. A photodiode region may be defined in the epitaxial layer 304.

As illustrated in FIG. 4B, the carrier Si substrate 308 may be bonded to an upper end of the Si substrate 300 in which the CMOS process has been performed for thinning a wafer, through a wafer bonding process, in accordance with embodiments.

In embodiments, as illustrated in FIG. 4C, the carrier Si substrate 308 may be fixed. As illustrated in FIG. 4D, the Si substrate 300 and the BOX 302 may be removed by performing a grinding and chemical mechanical polishing (CMP) process on the Si substrate 300, in accordance with embodiments. In embodiments, when the Si substrate 300 is an SOI wafer, both the Si substrate 300 and the BOX 302 may be removed through the grinding and CMP process. However, when the Si substrate 300 is not a SOI wafer, the Si substrate 300 may be removed through a dry or wet etching process, in accordance with embodiments. When removing the Si substrate 300 through the dry or wet etching process, the Si substrate 300 may be partially left to have a thickness of about 0.5 μm to about 5 μm, in accordance with embodiments.

In embodiments, deep trenches 310 for separating pixel regions may be formed by etching partial regions of the epitaxial layer 304. A description on an example process of forming the deep trench 310 follows. A photoresist pattern may be first formed on the epitaxial layer 304. The partial regions of the epitaxial layer 304 may then be slightly etched to pass through the epitaxial layer 304 by performing a dry etching process that uses the photoresist pattern as an etch mask, thereby forming the deep trench 310. The photoresist pattern may then be removed through a strip process and then a cleaning and annealing process may be performed.

As described above (in accordance with embodiments), the deep trench 310 may be formed to pass through the partial regions of the epitaxial layer 304. In embodiments, by deeply etching the partial regions of the epitaxial layer 304, the deep trench 310 may be formed to almost pass through the epitaxial layer 304. In embodiments, the width of the deep trench 310 may be between approximately 0.001 μm to 5 μm.

In embodiments, as illustrated in FIG. 4E, the first passivation layer 312 may be deposited on the epitaxial layer 304 with the deep trench 310 formed therein by using a dielectric material. The light shielding layer 314 may be formed on a top region of the first passivation layer 312 corresponding to the deep trench 310. The second passivation layer 316 may be formed on the first passivation layer 312 on which the light shielding layer 314 has been formed. The color filters 318 and the microlens 320 may be sequentially formed on a top region of the second passivation layer 316 (e.g. over a portion in which the deep trench 310 has been formed).

As described above, according to embodiments, the deep trench 310 may be formed by etching a partial region of the epitaxial layer 304 that may be the photodiode region. The color filter 318 and the microlens 320 may be formed over the partial region of the epitaxial layer 304, thereby manufacturing a backside illumination image sensor that can substantially minimize interface between adjacent pixels.

In embodiments, the deep trench for separating pixels may be formed by patterning the epitaxial layer in which the photodiode region may be defined, and then the color filter and the lens may be sequentially formed on a region corresponding to the epitaxial layer separated by the deep trench, thus minimizing an interference effect between adjacent pixels.

While embodiments have been shown and described, it will be understood by those skilled in the art that various changes and modification may be made without departing the scope of the embodiments as defined the following claims.

What is claimed is:

1. A method comprising:
bonding a first substrate and a second substrate, wherein the first substrate comprises an epitaxial layer in which a photodiode region is defined;
removing the first substrate to expose the epitaxial layer;
patterning the epitaxial layer to form a deep trench configured to separate pixels;
forming a first passivation layer at least one of on or over the epitaxial layer; and
sequentially forming a color filter and a lens on a top region of the first passivation layer corresponding to the epitaxial layer separated by the deep trench.

2. The method of claim 1, wherein the method is a method of manufacturing a backside illumination CMOS image sensor.

3. The method of claim 1, wherein said forming the deep trench comprises patterning the epitaxial layer to partially pass through the epitaxial layer.

4. The method of claim 1, wherein said forming the deep trench comprises patterning the epitaxial layer to form the deep trench, wherein the deep trench passes through a partial region of the epitaxial layer during patterning.

5. The method of claim 1, comprising forming a light shielding layer at least one of on or a region of the first passivation layer corresponding to the deep trench.

6. The method of claim 5, comprising forming a second passivation layer at least one of on or over the light shielding layer in which the first passivation layer has been formed, wherein said sequentially forming the color filter and the lens comprises sequentially forming the color filter and the lens at least one of on or over the second passivation layer.

7. The method of claim 1, wherein said forming the deep trench comprises:
forming a photoresist pattern at least one of on or over the epitaxial layer in a region of the photoresist pattern corresponding to the deep trench being opened; and
opening a partial region of the epitaxial layer to form the deep trench through an etching process, wherein the photoresist pattern is used as an etch mask during the etching process.

8. The method of claim 1, wherein the deep trench is gap-filled with material which is deposited in forming the first passivation layer.

9. An apparatus comprising an epitaxial layer in which a photodiode region is defined, wherein the apparatus comprises:
a deep trench formed for separating pixels by patterning the epitaxial layer;
a first passivation layer formed on the epitaxial layer with the deep trench formed therein; and
a color filter and a lens sequentially formed on a top region of the first passivation layer corresponding to the epitaxial layer region separated by the deep trench.

10. The apparatus of claim 9, wherein the apparatus is a backside illumination CMOS image sensor.

11. The apparatus of claim 9, wherein the deep trench is formed to partially pass through a partial region of the epitaxial layer.

12. The apparatus of claim 9, wherein the deep trench is formed to pass through a partial region of the epitaxial layer.

13. The apparatus of claim 9, comprising:
a light shielding layer formed at least one of on or over a region of the first passivation layer corresponding to the deep trench; and
a second passivation layer formed at least one of on or over the first passivation layer in which the light shielding layer has been formed.

14. The apparatus of claim 9, wherein the deep trench is gap-filled by the first passivation layer.

15. The apparatus of claim 9, wherein the deep trench has a width between approximately 0.001 μm to 5 μm.
